(19) United States
(12) Patent Application Publication
(10) Pub. No.: US 2014/0367767 A1
(43) Pub. Date: Dec. 18, 2014

(54) SEMICONDUCTOR DEVICE AND MANUFACTURING METHOD THEREOF

(71) Applicant: Kabushiki Kaisha Toshiba, Minato-ku (JP)

(72) Inventors: Takeshi Shundo, Yokkaichi-shi (JP); Kazuhiro Matsuo, Yokkaichi-shi (JP); Ryota Fujitsuka, Yokkaichi-shi (JP)

(73) Assignee: Kabushiki Kaisha Toshiba, Minato-ku (JP)

(21) Appl. No.: 14/012,068

(22) Filed: Aug. 28, 2013

Related U.S. Application Data
(60) Provisional application No. 61/835,049, filed on Jun. 14, 2013.

(51) Int. Cl. H01L 29/49; H01L 29/66; H01L 29/792

(52) U.S. Cl. CPC H01L 29/4983; H01L 29/792; H01L 29/66833
USPC 257/326; 438/591

(57) ABSTRACT

A semiconductor device according to the present embodiment includes a semiconductor substrate. An insulating film is provided on the semiconductor substrate. A gate electrode is provided on the insulating film. An SiOCN film covers side surfaces of the gate electrode. A silicon oxide film may be provided between the respective side surfaces of the gate electrode and the SiOCN film.

### CROSS REFERENCE TO RELATED APPLICATIONS

This application is based upon and claims the benefit of priority from the prior U.S. Provisional Patent Application No. 61/835,049, filed on Jun. 14, 2013, the entire contents of which are incorporated herein by reference.

### FIELD

The embodiments of the present invention relate to a semiconductor device and a manufacturing method thereof.

### BACKGROUND

The side surfaces of the gate electrodes of memory cells in a NAND flash EEPROM (Electrically Erasable Programmable Read-Only Memory) or the like are conventionally covered with a silicon oxide film or a silicon nitride film. When the silicon oxide film is used as a sidewall film for the gate electrodes, the silicon oxide film serving as the sidewall film for the gate electrode is etched in a wet etching process for removing residues after implanting impurities in regions between adjacent ones of the gate electrodes of the memory cells. In this case, such a problem occurs that the gate electrodes are not protected, a metal film provided on, for example, contact gate electrodes is oxidized, and that gate resistances rise. Furthermore, in the wet etching process, shallow trench isolations (STI) are also etched. This increases the probability of collapsing of the gate electrodes of the memory cells.

On the other hand, when the silicon nitride film is used as a sidewall film for the gate electrodes, such a problem occurs that the metal film on the contact gate electrodes is nitrided by the silicon nitride film and that a gate resistance rises. Furthermore, the silicon nitride film tends to hold fixed electric charges and has a higher dielectric constant than that of the silicon oxide film. For these reasons, a change in a threshold voltage of the memory cells and proximity and interference effects between the memory cells become problems.

### BRIEF DESCRIPTION OF THE DRAWINGS

FIG. 1 shows an example of a configuration of a semiconductor storage device according to a first embodiment;

FIG. 2 is a cross-sectional view showing an example of structures of one NAND string NS and the selection gate transistors SGD and SGS;

FIG. 3 is a cross-sectional view showing an example of a configuration of the memory cells MC according to the first embodiment;

FIG. 4 is a cross-sectional view showing an example of a gate electrode TRG of one transistor TR in peripheral circuits or the gate electrode SG of one of the selection gate transistors SGD and SGS;

FIGS. 5 to 13B are cross-sectional views showing an example of a manufacturing method of the NAND flash EEPROM according to the first embodiment;

FIG. 14 is a cross-sectional view showing an example of a configuration of the memory cells MC according to a modification of the first embodiment;

FIG. 15 is a cross-sectional view showing an example of a configuration of the memory cells MC according to a second embodiment; and

FIGS. 16 and 17 are cross-sectional views showing an example of a manufacturing method of the memory cells MC according to the second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the present embodiment includes a semiconductor substrate. An insulating film is provided on the semiconductor substrate. A gate electrode is provided on the insulating film. An SiOCN film covers side surfaces of the gate electrode.

### First Embodiment

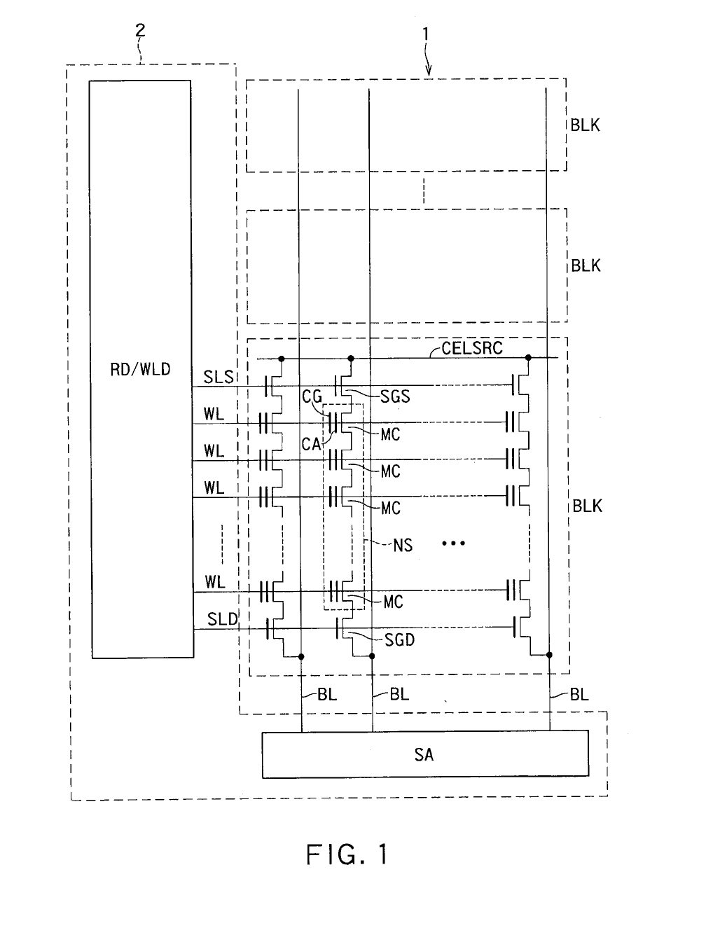

FIG. 1 shows an example of a configuration of a semiconductor storage device according to a first embodiment. The semiconductor storage device is, for example, a NAND flash EEPROM (hereinafter, also simply “memory”). The memory includes a memory cell array 1 in which a plurality of memory cells MC are arranged two-dimensionally in a matrix and a peripheral circuit region 2 controlling the memory cell array 1.

The memory cell array 1 includes a plurality of blocks BLK and each block BLK includes a plurality of NAND strings NS. The block BLK is a data erasure unit. Each NAND string NS includes a plurality of memory cells MC connected in series. The memory cells MC on both ends of each NAND string NS are connected to selection gate transistors SGD and SGS, respectively. The memory cells MC on one end of the memory cell array 1 are connected to bit lines BL via the selection gate transistors SGD, respectively, whereas the memory cells MC on the other end of the memory cell array 1 are connected to a cell source CELSRC via the selection gate transistors SGS, respectively.

Each of a plurality of word line WL is connected to control gates CG of the memory cells MC arrayed in a row direction. Selection gate lines SLD and SLS are connected to gates of the selection gate transistors SGD and SGS, respectively. The word lines WL and the selection gate lines SLS and SLD are driven by a row decoder RD and a word line driver WLD.

Each of the bit lines BL is connected to the NAND strings NS via the selection gate transistors SGD. The bit lines BL are also connected to sense amplifier circuits SA, respectively. A plurality of memory cells MC connected to one word line WL constitute a page that is a unit of collective data reading and data writing.

The selection gate lines SLS and SLD drive the selection gate transistors SGS and SGD, respectively, thereby connecting one NAND string NS between one bit line BL and the cell source CELSRC. The word line driver WLD drives unselected word lines WL, thereby turning on unselected memory cells MC. The sense amplifier SA can thereby apply a voltage to a selected memory cell MC via one bit line BL. The sense amplifier SA can thus detect data stored in the selected memory cell MC or write data to the selected memory cell MC.

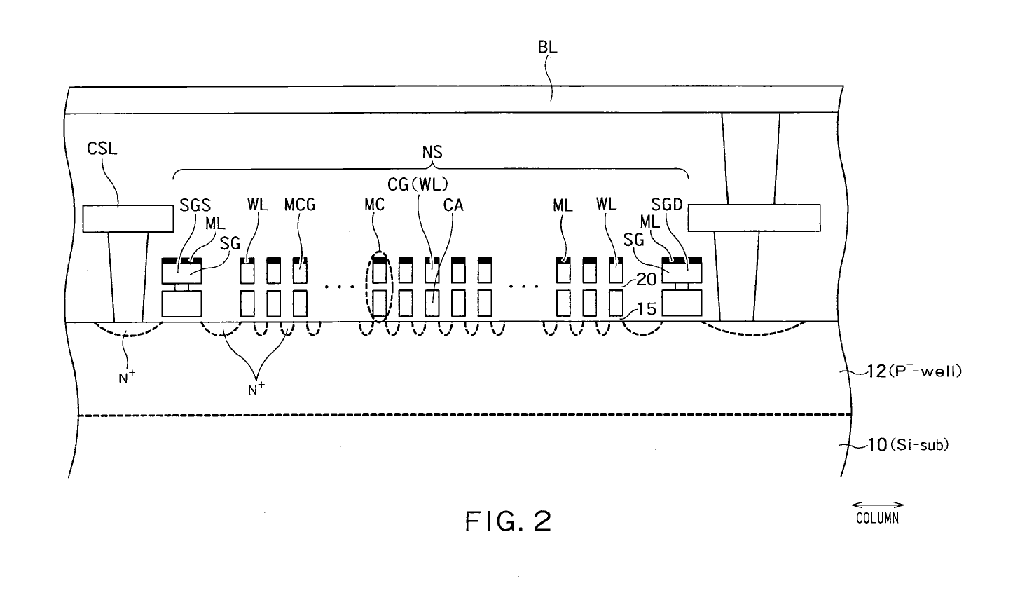

FIG. 2 is a cross-sectional view showing an example of structures of one NAND string NS and the selection gate transistors SGD and SGS. The NAND string NS is formed on a P-well 12 formed on a silicon substrate 10. A cell source line CSL is connected to the source-side selection gate transistor SGS connected to a source side of the NAND string NS. On the other hand, one bit line BL is connected to the drain-side selection gate transistor SGD connected to a drain side of the NAND string NS.

Each pair of memory cells MC adjacent in a column direction shares an n⁺ diffused layer DIF. The memory cells MC are thereby connected in series between the selection gate transistors SGD and SGS.

Each memory cell MC includes a charge accumulation layer CA provided on the silicon substrate 10 via a tunnel gate dielectric film 15 and the control gate CG provided on the charge accumulation layer CA via an inter-gate dielectric film 20.

Gate electrodes SG of the selection gate transistors SGD and SGS are made of the same material as that of the charge accumulation layers CA and the control gates CG of the memory cells MC. However, a part of the inter-gate dielectric film 20 between the charge accumulation layer CA and the control gate CG is removed, thereby electrically connecting the charge accumulation layer CA to the control gate CG.

Metal films ML are provided on gate electrodes MCG of the memory cells MC and on the gate electrodes SG of the selection gate transistors SGD and SGS, respectively, to reduce gate resistances and word line resistances. A barrier film (not shown) can be formed between each of the gate electrodes MCG and SG and each of the metal films ML to prevent diffusion of a metal material (tungsten, for example) of the metal film ML toward the gate electrode MCG or SG.

The gate electrodes MCG and the metal films ML extend in the row direction and also function as the word lines WL. In the following explanations, the metal film ML is often expressed as being included in the gate electrode MCG or the word line WL.

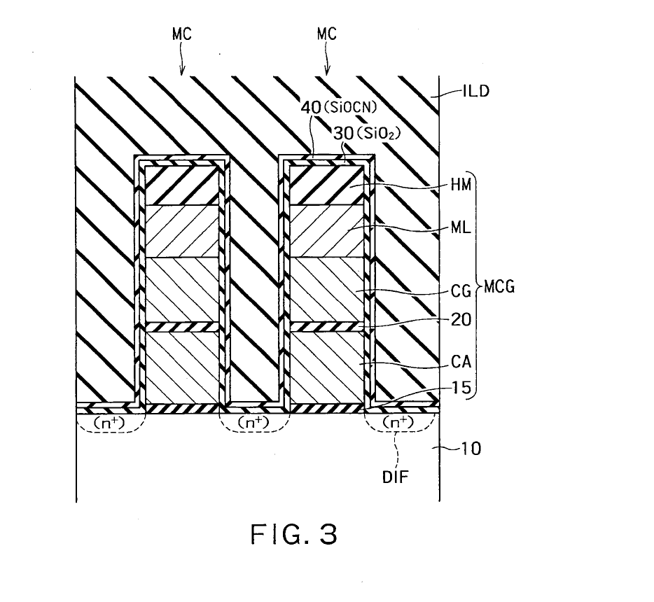

FIG. 3 is a cross-sectional view showing an example of a configuration of the memory cells MC according to the first embodiment. FIG. 3 shows cross-sections of the memory cells MC in a direction along a certain NAND string NS.

As shown in FIG. 3, the memory cells MC are formed on a surface of the semiconductor substrate 10. Each of the memory cells MC includes the tunnel gate dielectric film 15, the charge accumulation layer CA, the inter-gate dielectric film 20, the control gate CG, the metal film ML, and a hard mask HM. The tunnel gate dielectric film 15 is provided on the semiconductor substrate 10. The charge accumulation layer CA is provided on the tunnel gate dielectric film 15. The inter-gate dielectric film 20 is provided on the charge accumulation layer CA. The control gate CG is provided on the inter-gate dielectric film 20. The metal film ML is provided on the control gate CG. The hard mask HM is provided on the metal film ML. As can be understood, the gate electrodes MCG of the memory cells MC are provided on the semiconductor substrate 10 via the tunnel gate dielectric films 15, respectively. The gate electrode MCG includes the charge accumulation layer CA, the control gate CG, and the metal film ML. Alternatively, the gate electrode MCG can have a gate electrode structure including the inter-gate dielectric film 20 and the hard mask HM in addition to the charge accumulation layer CA, the control gate CG, and the metal film ML.

The tunnel gate dielectric film 15 is formed using an insulating film, for example, a silicon oxide film. The charge accumulation layer CA is formed using a material, for example, polysilicon or a multilayer film constituted by polysilicon and a silicon nitride film. The inter-gate dielectric film 20 is an insulating film, for example, a silicon oxide film, a silicon nitride film, or a High-k film. The control gate CG is formed using a conducting film made of, for example, doped polysilicon. The metal film ML is formed using low-resistance metal, for example, tungsten. When there is a barrier film (not shown) between the control gate CG and the metal film ML, the barrier film is formed using metal silicide, for example, titanium silicide.

The memory cell MC according to the first embodiment further includes a silicon oxide film 30 and an SiOCN film 40. The silicon oxide film 30 and the SiOCN film 40 cover side surfaces of the charge accumulation layer CA, the inter-gate dielectric film 20, the control gate CG, the metal film ML, and the hard mask HM. The SiOCN film 40 covers the side surfaces of the charge accumulation layer CA, the inter-gate dielectric film 20, the control gate CG, the metal film ML, and the hard mask HM via the silicon oxide film 30. A single-layer film constituted by an SiOCN film or a multilayer film including an SiOCN film can be used as the SiOCN film 40. The silicon oxide film 30 and the SiOCN film 40 are also formed on an upper surface of the hard mask HM and on the surface of the semiconductor substrate 10.

Furthermore, an inter-layer dielectric film ILD is provided on the SiOCN film 40. That is, the inter-layer dielectric film ILD is deposited between adjacent ones of the gate electrodes MCG and on the gate electrodes MCG. As already described, the n⁺ impurity diffused layer DIF is formed between memory cells MC adjacent in the direction along the NAND string NS.

The memory cells MC accumulate electric charges (electrons, for example) in the charge accumulation layers CA via the tunnel gate dielectric films 15 or emit electric charges from the charge accumulation layers CA via the tunnel gate dielectric films 15 according to voltages of the control gates CG, respectively. The conductive state of the memory cell MC changes depending on an amount of electric charges (an amount of charges) accumulated in the charge accumulation layer CA. It is thereby possible to write logical data to the memory cell MC. The sense amplifier SA detects the conductive state of the memory cell MC, thereby enabling to read the logic of data stored in the memory cell MC.

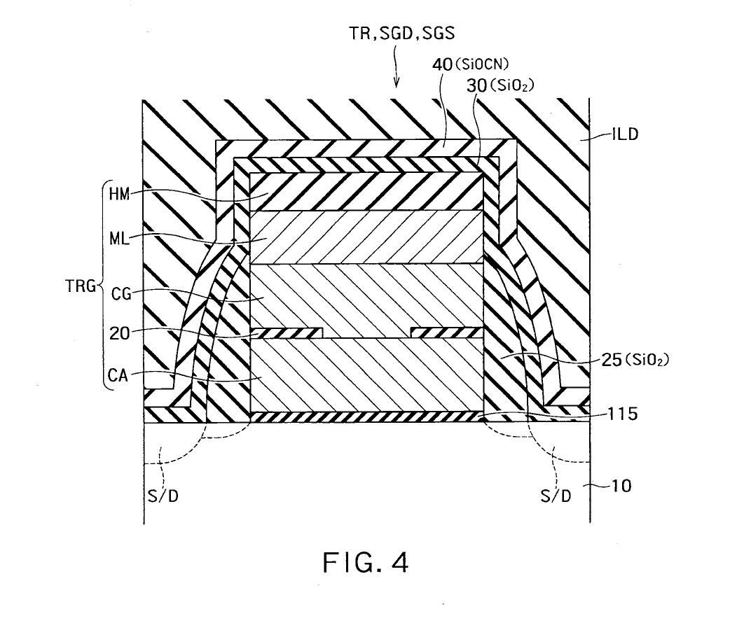

FIG. 4 is a cross-sectional view showing an example of a gate electrode TRG of one transistor TR in peripheral circuits or the gate electrode SG of one of the selection gate transistors SGD and SGS. The transistor TR in the peripheral circuits is explained below. The transistor TR is formed on the surface of the semiconductor substrate 10. Similarly to the memory cell MC, the transistor TR includes a gate dielectric film 115, the charge accumulation layer CA, the inter-gate dielectric film 20, the control gate CG, the metal film ML, and the hard mask HM. While the gate dielectric film 115 can be configured similarly to the tunnel gate dielectric film 15 shown in FIG. 3, the gate dielectric film 115 can be thicker than the tunnel gate dielectric film 15. A part of the inter-gate dielectric film 20 is etched, whereby the control gate CG is electrically connected to the charge accumulation layer CA. The control gate CG and the charge accumulation layer CA thereby function as one gate electrode TRG.

The transistor TR further includes spacers 25, the silicon oxide film 30, and the SiOCN film 40. The spacers 25 are formed on the side surfaces of the charge accumulation layer CA, the inter-gate dielectric film 20, and the control gate CG, and used as spacers at the time of forming a source or drain diffused layer S/D, respectively. Furthermore, the silicon oxide film 30 and the SiOCN film 40 cover the side surfaces of the charge accumulation layer CA, the inter-gate dielectric film 20, the control gate CG, the metal film ML, and the hard mask HM. The SiOCN film 40 covers the side surfaces of the charge accumulation layer CA, the inter-gate dielectric film 20, the control gate CG, the metal film ML, and the hard mask HM via the silicon oxide film 30 and the spacers 25. The silicon oxide film 30 and the SiOCN film 40 are also formed on the upper surface of the hard mask HM and on the surface of the semiconductor substrate 10.

As shown in FIGS. 3 and 4, in the first embodiment, the silicon oxide film 30 and the SiOCN film 40 cover the side surfaces of the charge accumulation layer CA, the inter-gate dielectric film 20, the control gate CG, the metal film ML, and the hard mask HM. The SiOCN film 40 is higher than the silicon oxide film 30 in resistance against wet etching (a dilute hydrogen fluoride (DHF) treatment, for example) (“wet etching resistance”). Accordingly, in a wet etching process performed to remove residues generated by impurity implantation, the SiOCN film 40 can protect the silicon oxide film 30 and suppress the silicon oxide film 30 from being etched. That is, the SiOCN film 40 can protect the side surfaces of the silicon oxide film 30, the metal film ML, the control gate CG, the inter-gate dielectric film 20, the charge accumulation layer CA, and the tunnel gate dielectric film 15 or the gate dielectric film 115 from being etched. The SiOCN film 40 and the silicon oxide film 30 can thereby protect the gate electrodes MCG of the memory cells MC or the gate electrodes TRG of the transistors TR and suppress the side surfaces of the metal film ML from being oxidized in a later process. By suppressing oxidization of the metal film ML, the gate resistances can be kept low.

The SiOCN film 40 also covers the surface of the semiconductor substrate 10 and those of shallow trench isolations STI (not shown). Therefore, the shallow trench isolations STI located between adjacent ones of the NAND strings NS are protected by the SiOCN film 40 and not etched in the wet etching process. It is thereby possible to suppress the gate electrodes MCG of the memory cells MC from collapsing.

The SiOCN film 40 has a lower dielectric constant than that of the silicon nitride film. Therefore, the SiOCN film 40 can suppress a capacitance between the transistors TR and that between the memory cells MC as compared with the silicon nitride film. This can suppress data interference among the transistors TR or among the memory cells MC. Moreover, it is more difficult for the SiOCN film 40 to trap the fixed electric charges than the silicon nitride film. Therefore, a change in a threshold voltage of the transistors TR or the memory cells MC resulting from the fixed electric charges can be suppressed by using the SiOCN film 40 as a sidewall film.

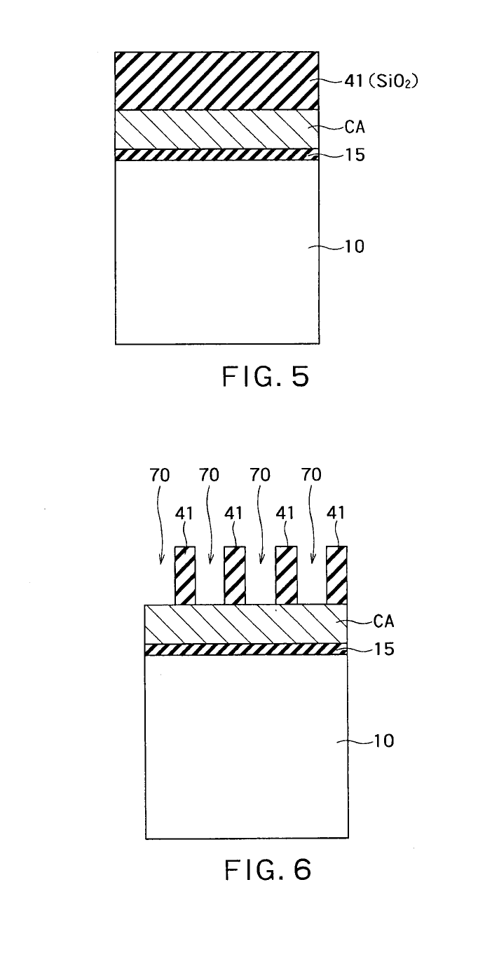

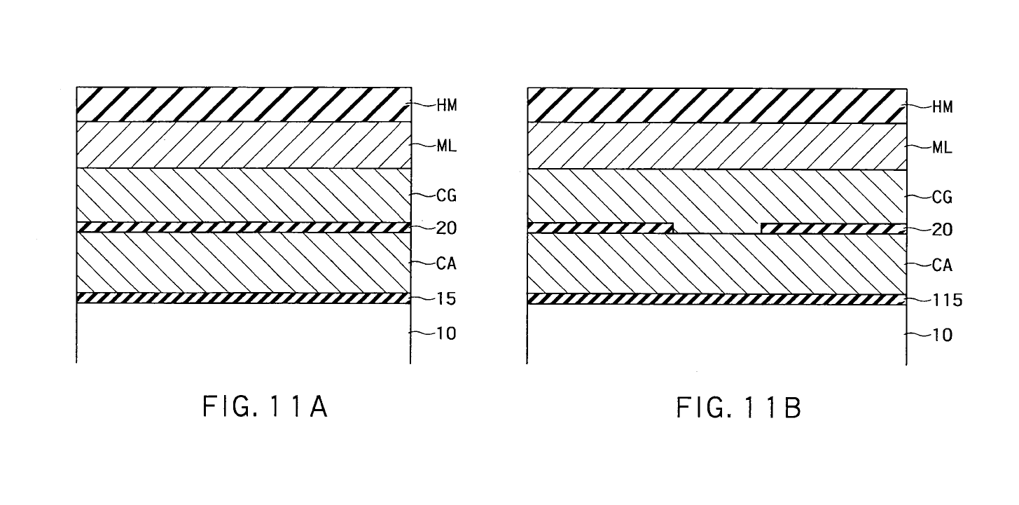

FIGS. 5 to 13 are cross-sectional views showing an example of a manufacturing method of the NAND flash EEPROM according to the first embodiment. FIGS. 5 to 10 show cross-sections in an orthogonal direction to the direction along the NAND strings NS. FIGS. 11A to 13B show cross-sections in the direction along the NAND strings NS.

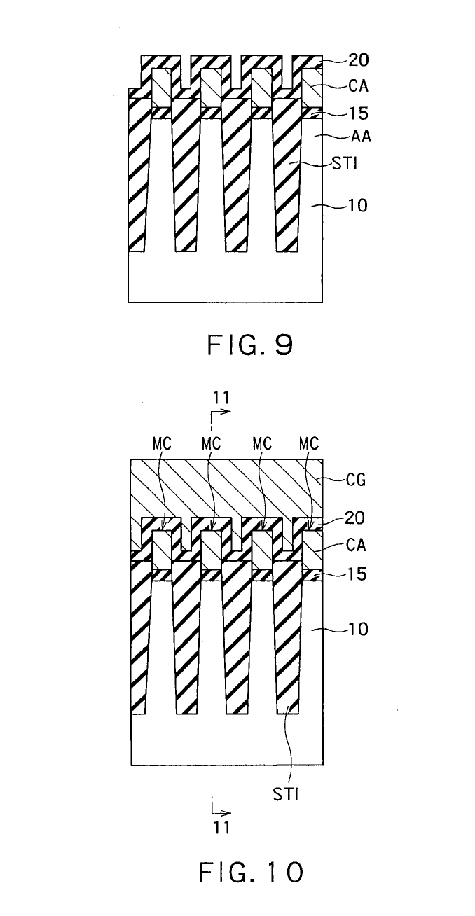

First, as shown in FIG. 5, the tunnel gate dielectric film 15 and the gate dielectric film 115 (see FIGS. 4, 11B to 13B regarding the gate dielectric film 115) are formed on the semiconductor substrate 10. The tunnel gate dielectric film 15 and the gate dielectric film 115 are formed using a silicon oxide film formed by, for example, thermally oxidizing the semiconductor substrate 10. The tunnel gate dielectric film 15 and the gate dielectric film 115 can be formed either simultaneously or separately. A material of the charge accumulation layers CA is deposited on the tunnel gate dielectric film 15 and the gate dielectric film 115. The charge accumulation layers CA are formed using, for example, polysilicon. A mask material 41 is deposited on the material of the charge accumulation layers CA. The mask material 41 is formed using an insulating film, for example, the silicon oxide film or the silicon nitride film. The mask material 41 is processed into a layout pattern of the shallow trench isolations STI using a sidewall transfer process, a lithographic technique, and an etching technique. In a memory cell region, the shallow trench isolations STI are formed between adjacent ones of active areas in which the NAND strings NS are formed, respectively. Therefore, the shallow trench isolations STI are formed into a stripe layout pattern along the NAND strings NS (see FIG. 9).

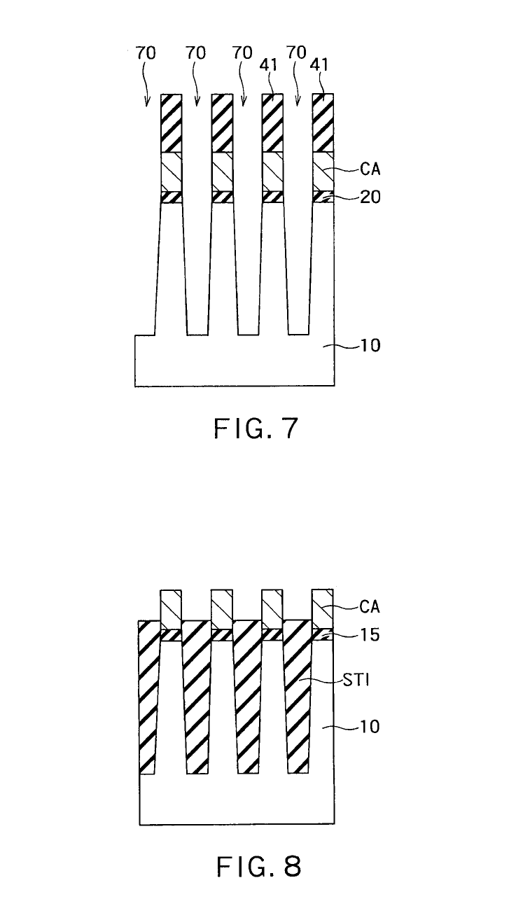

Using the mask material 41 as a mask, the material of the charge accumulation layers CA, the tunnel gate dielectric film 15, and the semiconductor substrate 10 are then processed by an RIE (Reactive Ion Etching) method. Trenches 70 used as the shallow trench isolations STI are thereby formed as shown in FIG. 7. In the peripheral circuit region, the gate dielectric films 115, the charge accumulation layers CA, and the shallow trench isolations STI are formed similarly to the memory cell region although layout patterns in the peripheral circuit region differ from those in the memory cell region.

An element-isolation insulating film STI is then filled in the trenches 70. The element-isolation insulating film STI is then planarized until upper surfaces of the charge accumulation layers CA are exposed, and the element-isolation insulating film STI is further etched back. As shown in FIG. 8, upper portions of the side surfaces of the charge accumulation layers CA are thereby exposed.

As shown in FIG. 9, the inter-gate dielectric film 20 is then deposited along the upper surfaces and the side surfaces of the charge accumulation layers CA. In the peripheral circuit region, a part of the inter-gate dielectric film 20 on the charge accumulation layers CA is removed using the lithographic technique and the etching technique to connect the control gates CG to the charge accumulation layers CA, respectively (see FIG. 11B).

As shown in FIG. 10, a material of the control gates CG is then deposited on the inter-gate dielectric film 20. The material of the control gates CG is formed using, for example, polysilicon or metal silicide. The material of the control gates CG faces the upper surfaces and side surfaces of the charge accumulation layers CA of the memory cells MC via the inter-gate dielectric film 20.

FIGS. 11A, 12A, and 13A show the cross-sections of the memory cell (or the memory cells) MC along one NAND string NS. That is, FIGS. 11A, 12A, and 13A show the cross-sections of the memory cell (or the memory cells) MC taken along a line 11-11 of FIG. 10. FIGS. 11B, 12B, and 13B show the cross-section of one transistor TR in the peripheral circuits or the selection gate transistor SGD or SGS.

After planarizing the material of the control gates CG, materials of the metal films ML and the hard masks HM are deposited on the material of the control gates CG. The hard mask HM is formed using, for example, a silicon nitride film. A structure shown in FIGS. 11A and 11B is thereby obtained.

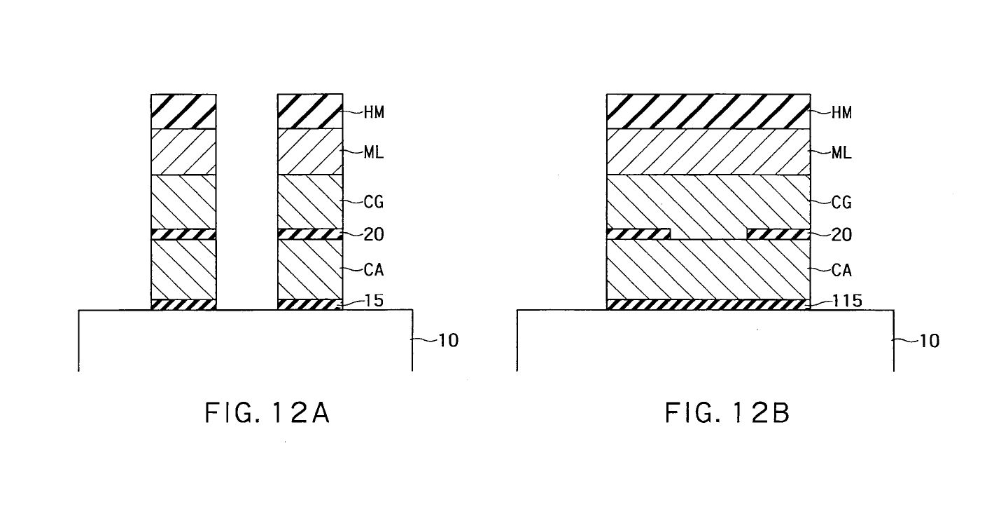

The hard mask HM is processed into a layout pattern of the word lines WL using the side transfer process, the lithographic technique, and the etching technique. Using the hard masks HM as masks, the materials of the metal films ML and the control gates CG and those of the inter-gate dielectric films 20 and the charge accumulation layers CG are etched. A structure shown in FIGS. 12A and 12B is thereby obtained.

The materials of the metal films ML and the control gates CG are processed according to the layout pattern of the word lines WL, thereby forming the gate electrodes MCG (word lines WL) extending in the orthogonal direction to an extension direction of the NAND strings NS. The material of the charge accumulation layer CA is subjected to both processing according to the layout pattern of the shallow trench isolations STI and processing according to the layout pattern of the word lines WL. The charge accumulation layer CA is thereby separated to correspond to the respective memory cells MC and the resultant charge accumulation layers CA are provided to correspond to the respective memory cells MC.

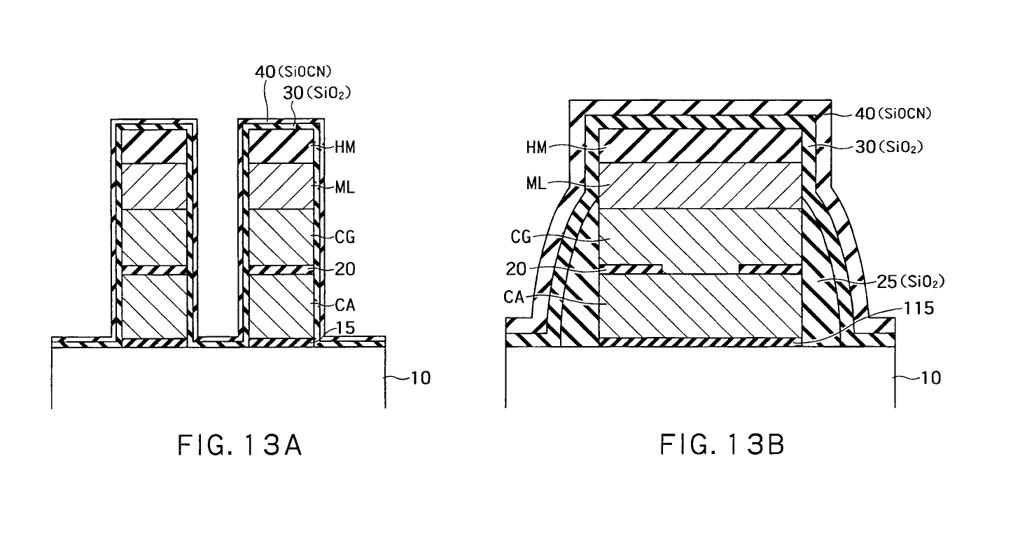

The spacers 25 are then formed on the side surfaces of the transistors TR, respectively, in the peripheral circuits. For example, a material (a silicon oxide film, for example) of the spacers 25 is deposited on the peripheral circuit region and etched back. Accordingly, the spacers 25 are left on the side surfaces of the transistors TR, respectively, as shown in FIG. 13B. Before forming the spacers 25, an extension layer can be formed on both sides of the gate electrodes of the transistors TR, respectively.

The silicon oxide film 30 and the SiOCN film 40 are then deposited on the side surfaces of the charge accumulation layers CG, the inter-gate dielectric films 20, the control gates CG, the metal films ML, and the hard masks HM. The silicon oxide film 30 and the SiOCN film 40 are also deposited on the semiconductor substrate 10 and the shallow trench isolations STI (FIG. 10). The silicon oxide film 30 is formed at a low temperature (equal to or lower than 400 degrees, for example) to suppress the side surfaces of the metal films ML from being oxidized. The SiOCN film 40 is formed at a low temperature (400 to 500 degrees, for example) to suppress the side surfaces of the metal films ML from being oxidized. A structure shown in FIGS. 13A and 13B is thereby obtained.

By increasing the carbon content of the SiOCN film 40, the wet etching resistance of the SiOCN film 40 can be increased. However, when the carbon content is too high, the dielectric constant of the SiOCN film 40 increases. When the nitrogen content of the SiOCN film 40 is increased, the dielectric constant of the SiOCN film 40 can be reduced to some extent. When the nitrogen content is too high, the fixed electric charges tend to be generated in the SiOCN film 40. When the oxygen content of the SiOCN film 40 is increased, the dielectric constant of the SiOCN film 40 can be reduced. However, when the oxygen content is too high, the wet etching resistance of the SiOCN film 40 lowers. Therefore, by appropriately adjusting the carbon and nitrogen (or oxygen) contents, the SiOCN film 40 can have both a high wet etching resistance and a low dielectric constant without generating so many fixed electric charges. For example, the SiOCN film 40 contains about 1 to 10 atom % of carbon and about 1 to 30 atom % of nitrogen. The SiOCN film 40 can thereby achieve the above effects.

Next, impurities are implanted between adjacent ones of the gate electrodes MCG of the memory cells MC, thereby forming the n⁺ diffused layers DIF as shown in FIG. 3. At this time, the source or drain diffused layers S/D of the transistors TR in the peripheral circuits shown in FIG. 4 can be formed simultaneously with the n⁺ diffused layers DIF of the memory cells MC.

Residues are generated by the impurity implantation at the time of forming the n⁺ diffused layers DIF. Therefore, a residue removal treatment is performed using the wet etching. For example, a DHF solution is used in the wet etching. At this time, because the SiOCN film 40 covers the silicon oxide film 30, the silicon oxide film 30 protects the side surfaces of the charge accumulation layers CA, the inter-gate dielectric films 20, the control gates CG, the metal films ML, and the hard masks HM without being removed. That is, the SiOCN film 40 protects the silicon oxide film 30 from wet etching targets, and the silicon oxide film 30 protects the side surfaces of the charge accumulation layers CA, the inter-gate dielectric films 20, the control gates CG, the metal films ML, and the hard masks HM. Similarly, the gate electrodes TRG of the transistors TR in the peripheral circuits are protected by the silicon oxide film 30 and the SiOCN film 40.

Thereafter, the inter-layer dielectric film ILD, the bit lines BL, and the like are formed, thereby completing the NAND flash EEPROM according to the first embodiment.

As described above, with the manufacturing method according to the first embodiment, the silicon oxide film 30 and the SiOCN film 40 cover the side surfaces of the gate electrodes MCG of the respective memory cells MC and those of the gate electrodes TRG of the respective transistors TR. The SiOCN film 40 has the higher wet etching resistance than that of the silicon oxide film 30. Therefore, in the wet etching process, the SiOCN film 40 can protect the silicon oxide film 30 and suppress the silicon oxide film 30 from being etched. The SiOCN film 40 and the silicon oxide film 30 can thereby protect the gate electrodes MCG and TRG and suppress the side surfaces of the metal films ML from being oxidized in the subsequent processes. By suppressing the oxidization of the metal films ML, the gate resistances can be kept low.

Furthermore, the SiOCN film 40 also covers the surfaces of the semiconductor substrate 10 and the shallow trench isolations STI. Therefore, the shallow trench isolations STI located between adjacent ones of the NAND strings NS are protected by the SiOCN film 40 and not etched in the wet etching process mentioned above. It is thereby possible to suppress collapsing of the gate electrodes MCG of the memory cells MC.

The SiOCN film 40 has the lower dielectric constant than those of the silicon nitride film and SiC. Therefore, the SiOCN film 40 can suppress data interference among the transistors TR or among the memory cells MC. Furthermore, it is more difficult for the SiOCN film 40 to trap the fixed electric charges than the silicon nitride film. Therefore, by using the SiOCN film 40 in place of the silicon nitride film as the sidewall film, it is possible to suppress a change in a threshold voltage of the transistors TR or the memory cells MC resulting from the fixed electric charges. In this way, the SiOCN film 40 can resolve the tradeoff between the wet etching resistance and the low dielectric constant.

### (Modification)

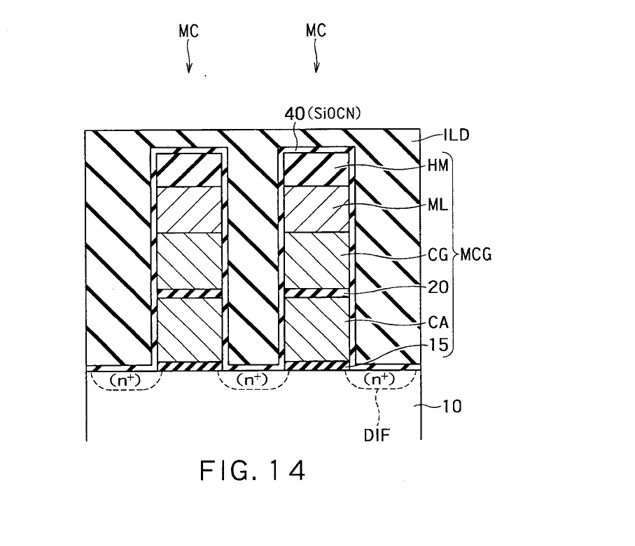

FIG. 14 is a cross-sectional view showing an example of a configuration of the memory cells MC according to a modification of the first embodiment. In the modification, the silicon oxide film 30 is not provided and the SiOCN film 40 directly covers the side surfaces of the gate electrodes MCG and TRG. That is, the single-layer SiOCN film 40 protects the side surfaces of the gate electrodes MCG and TRG. The side surfaces of the gate electrodes TRG of the transistors TR in the peripheral circuits are covered with the spacers 25 and the SiOCN film 40.

Identical effects as those in the first embodiment can be achieved also in the modification. Furthermore, because the silicon oxide film 30 does not need to be formed in the modification, the manufacturing process can be shortened.

### Second Embodiment

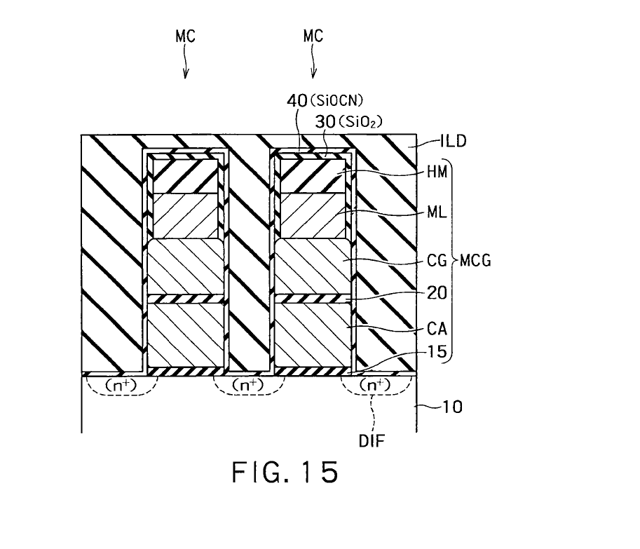

FIG. 15 is a cross-sectional view showing an example of a configuration of the memory cells MC according to a second embodiment. In the memory cells MC according to the second embodiment, the silicon oxide film 30 and the SiOCN film 40 cover the side surfaces of the metal films ML and the side surfaces and upper surfaces of the hard masks HM. The silicon oxide film 30 is not provided on the side surfaces of the control gates CG and the charge accumulation layers CA, and the SiOCN film 40 covers the side surfaces of the control gates CG and the charge accumulation layers CA. That is, the SiOCN film 40 directly covers the side surfaces of the charge accumulation layers CA, the inter-gate dielectric films 20, and the control gates CG and covers the side surfaces of the metal films ML via the silicon oxide film 30. Other configurations of the second embodiment can be identical to corresponding ones of the first embodiment.

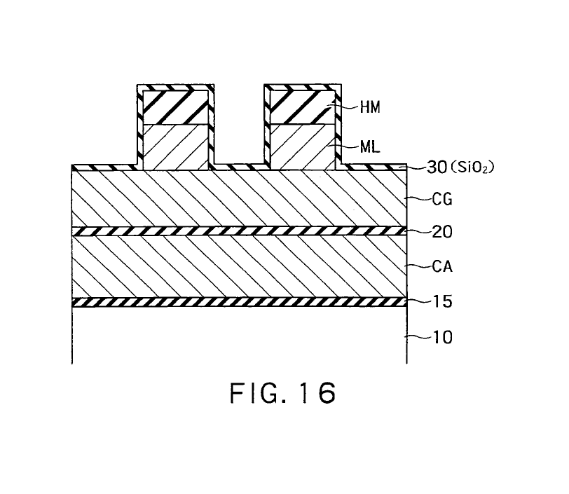

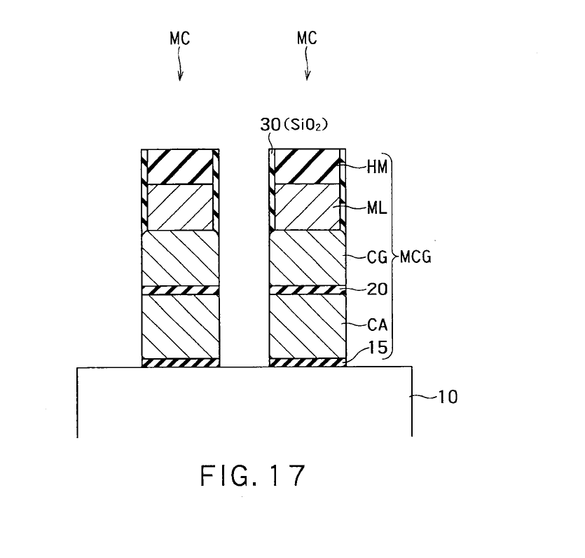

FIGS. 16 and 17 are cross-sectional views showing an example of a manufacturing method of the memory cells MC according to the second embodiment. After the processes shown in FIGS. 5 to 11, the hard mask HM is processed into the layout pattern of the word lines WL using the lithographic technique and the etching technique. Furthermore, using the hard masks HM as masks, the metal film ML is etched. A structure shown in FIG. 16 is thereby obtained. At this stage, the material of the control gates CG and those of the inter-gate dielectric films 20 and the charge accumulation layers CA are not processed yet.

As shown in FIG. 16, the silicon oxide film 30 is then deposited on the side surfaces of the metal films ML and the hard masks HM. The silicon oxide film 30 is formed at a low temperature (equal to or lower than 400 degrees, for example) to suppress oxidization of the side surfaces of the metal films ML.

Next, using anisotropic etching such as the RIE method, the material of the control gates CG and those of the inter-gate dielectric films 20 and the charge accumulation layers CA are processed. Accordingly, as shown in FIG. 17, the material of the control gates CG and those of the inter-gate dielectric films 20 and the charge accumulation layers CA can be processed while the side surfaces of the metal films ML and the hard masks HM are protected by the silicon oxide film 30. In this way, the oxidization of the side surfaces of the metal films ML can be suppressed as much as possible by shortening a time period for which the side surfaces of the metal films ML are exposed.

Next, as shown in FIG. 15, the SiOCN film 40 is deposited to cover the surface of the silicon oxide film 30 and the side surfaces of the control gates CG, the inter-gate dielectric films 20, and the charge accumulation layers CA.

Next, the n⁺ diffused layers DIF are formed as shown in FIG. 15 by implanting the impurities between adjacent ones of the gate electrodes MCG of the memory cells MC.

Next, to remove the residues generated at the time of forming the n⁺ diffused layers DIF, the residue removal treatment is performed using the wet etching. At this time, the SiOCN film 40 covers the surface of the silicon oxide film 30 and the side surfaces of the control gates CG, the inter-gate dielectric films 20, and the charge accumulation layers CA. Therefore, the silicon oxide film 30 protects the side surfaces of the metal films ML and the hard masks HM without being removed. Furthermore, the SiOCN film 40 can protect the side surfaces of the charge accumulation layers CA, the inter-gate dielectric films 20, and the control gates CG. The gate electrodes TRG of the transistors TR in the peripheral circuits are similarly protected by the silicon oxide film 30 and the SiOCN film 40.

Thereafter, the inter-layer dielectric film ILD, the bit lines BL, and the like are formed, thereby completing the NAND flash EEPROM according to the second embodiment.

According to the second embodiment, the side surfaces of the metal films ML are covered with the silicon oxide film 30 right after etching the metal film ML. This can shorten the time for exposing the metal films ML as much as possible. As a result, oxidization of the side surfaces of the metal films ML can be suppressed as much as possible.

Also in the second embodiment, the SiOCN film 40 protects the surface of the silicon oxide film 30 and the side surfaces of the charge accumulation layers CA, the inter-gate dielectric films 20, and the control gates CG. Therefore, the second embodiment can achieve identical effects at those in the first embodiment.

The gate electrodes TRG of the transistors TR in the peripheral circuits can be formed similarly to the gate electrodes MCG of the memory cells MC. In the gate electrodes TRG of the transistors TR, the silicon oxide film 30 covers the side surfaces of the metal films ML and the side surfaces and upper surfaces of the hard masks HM. The spacers 25 cover the side surfaces of the charge accumulation layers CA, the inter-gate dielectric films 20, and the control gates CG. The SiOCN film 40 covers the side surfaces and the upper surfaces of the gate electrodes TRG of the transistors TR via the silicon oxide film 30 and the spacers 25. The gate electrodes TRG of the transistors TR in the peripheral circuits can be thereby protected by the SiOCN film 40. Needless to mention, the gate electrodes TRG of the transistors TR in the peripheral circuits can be formed separately from the gate electrodes MCG of the memory cells MC.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
an insulating film provided on the semiconductor substrate;
a gate electrode provided on the insulating film; and
an SiOCN film covering side surfaces of the gate electrode.

2. The device of claim 1, further comprising a silicon oxide film provided between the respective side surfaces of the gate electrode and the SiOCN film.

3. The device of claim 1, wherein
the gate electrode is a gate electrode of a memory cell, the memory cell comprising:
a charge accumulation layer provided on the insulating film;
an inter-gate dielectric film provided on the charge accumulation layer;
a control gate provided on the inter-gate dielectric film; and
a metal film provided on the control gate, and
the SiOCN film covers respective side surfaces of the metal film, the charge accumulation layer, the inter-gate dielectric film, and the control gate.

4. The device of claim 1, wherein
the gate electrode is a gate electrode of a memory cell, the memory cell comprising:
a charge accumulation layer provided on the insulating film;
an inter-gate dielectric film provided on the charge accumulation layer;
a control gate provided on the inter-gate dielectric film; and
a metal film provided on the control gate,
wherein a silicon oxide film provided on the respective side surfaces of the metal film,
the SiOCN film covers respective side surfaces of the charge accumulation layer, the inter-gate dielectric film, and the control gate, and the SiOCN film covers respective side surfaces of the metal film via silicon oxide film.

5. The device of claim 4, wherein
the silicon oxide film is also provided on side surfaces of a hard mask provided on the metal film, and
the SiOCN film also covers the side surfaces of the hard mask provided on the metal film.

6. The device of claim 3, wherein the SiOCN film is also provided on side surfaces of a gate electrode of a transistor in a peripheral circuit region which is provided periphery of a cell array including a plurality of the memory cells.

7. The device of claim 4, wherein the SiOCN film is also provided on side surfaces of a gate electrode of a transistor in a peripheral circuit region which is provided periphery of a cell array including a plurality of the memory cells.

8. A manufacturing method of a semiconductor device comprising:
forming an insulating film on a semiconductor substrate;
forming a gate electrode on the insulating film; and
forming an SiOCN film in order to cover side surfaces of the gate electrode.

9. The method of claim 8, further comprising forming a silicon oxide film in order to cover the side surfaces of the gate electrode before the forming the SiOCN film.

10. The method of claim 8, wherein
the forming the gate electrode comprises:
forming a material of a charge accumulation layer on the insulating film;
forming an inter-gate dielectric film on the material of the charge accumulation layer;
forming a material of a control gate on the inter-gate dielectric film;
forming a metal film on the material of the control gate;
processing the metal film, the material of the control gate, the inter-gate dielectric film, and the material of the charge accumulation layer into a pattern of word lines, and
in the forming the SiOCN film, the SiOCN film covers respective side surfaces of the metal film, the control gate, the inter-gate dielectric film, and the charge accumulation layer.

11. The method of claim 8, wherein
the forming the gate electrode comprises:
forming a material of a charge accumulation layer on the insulating film;
forming an inter-gate dielectric film on the material of the charge accumulation layer;
forming a material of a control gate on the inter-gate dielectric film;
forming a metal film on the material of the control gate;
processing the metal film into a pattern of word lines;
forming a silicon oxide film covering respective side surfaces of the metal film;
processing the material of the control gate, the inter-gate dielectric film, and the material of the charge accumulation layer into a pattern of word lines, and
in the forming the SiOCN film, the SiOCN film covers respective side surfaces of the charge accumulation layer, the inter-gate dielectric film, and the control gate, and the SiOCN film covers respective side surfaces of the metal film via silicon oxide film.

12. The method of claim 10, wherein
the metal film, the material of the control gate, the inter-gate dielectric film, and the material of the charge accumulation layer are processed using a hard mask provided on the metal film as a mask, and
the SiOCN film also covers side surfaces of the hard mask.

13. The method of claim 11, wherein
the metal film, the material of the control gate, the inter-gate dielectric film, and the material of the charge accumulation layer are processed using a hard mask provided on the metal film as a mask, and
the SiOCN film also covers side surfaces of the hard mask.

14. The method of claim 10, wherein the SiOCN film is also provided on side surfaces of a gate electrode of a transistor in a peripheral circuit region which is provided periphery of a cell array including a plurality of the memory cells.

15. The method of claim 11, wherein the SiOCN film is also provided on side surfaces of a gate electrode of a transistor in a peripheral circuit region which is provided periphery of a cell array including a plurality of the memory cells.
